(19) United States
(12) Patent Application Publication
(10) Pub. No.: US 2024/0074109 A1
(43) Pub. Date: Feb. 29, 2024

(54) MIXED FLUID IMMERSION COOLING SYSTEM AND METHOD

(71) Applicant: Calaris Technologies, Inc., (US)

(72) Inventor: Rob Weber, Woodridge, IL (US)

(73) Assignee: Calaris Technologies, inc., (omitted)

(21) Appl. No.: 18/458,112

(22) Filed: Aug. 29, 2023

Related U.S. Application Data
(60) Provisional application No. 63/374,001, filed on Aug. 30, 2022.

(51) Int. Cl. H05K 7/20

(52) U.S. Cl. CPC H05K 7/203; H05K 7/20236; H05K 7/20263; H05K 7/20318; H05K 7/20327

(57) ABSTRACT

Described herein are examples of devices which include a cooling housing. The cooling housing includes a containment area. The containment includes a heat source to be cooled. The housing includes a heat exchanger coupled to the housing. The heat exchanger transfers heat from the containment area to an environment surrounding the cooling housing. The housing includes a first fluid positioned within the containment area and partially surrounding a first portion of the heat source. The housing includes at least one second fluid positioned within the containment area and partially surrounding at least one second portion of the heat source. The first fluid is substantially separate from the at least one second fluid. The housing includes a third fluid in thermal contact with a portion of the at least one second fluid and a portion of the heat exchanger.

### CROSS-REFERENCE TO RELATED APPLICATIONS

The present application claim priority to U.S. Provisional Patent Application No. 63/374,001 entitled “MIXED FLUID IMMERSION COOLING SYSTEM AND METHOD”, filed on Aug. 30, 2022. The entire contents of the above-listed application are hereby incorporated by reference for all purposes.

### BACKGROUND

Modern electronic devices produce significant amount of heat. As such, most modern electronic components require robust cooling systems.

### BRIEF DESCRIPTION OF THE DRAWINGS

The present description will be understood more fully when viewed in conjunction with the accompanying drawings of various examples of cooling systems. The description is not meant to limit the cooling systems to the specific examples. Rather, the specific examples depicted and described are provided for explanation and understanding of cooling systems. Throughout the description the drawings may be referred to as drawings, figures, and/or FIGs.

FIG. 1 illustrates a cross-section view of a cooling system, according to an embodiment.

FIG. 2 illustrates an operation of a cooling system, according to an embodiment.

FIG. 3 illustrates a cross-section view of another cooling system, according to an embodiment.

FIG. 4 illustrates a cross-section view of another cooling system, according to an embodiment.

FIG. 5 illustrates a block chart of a method for cooling heat sources, according to an embodiment.

### DETAILED DESCRIPTION

Cooling systems as disclosed herein will become better understood through a review of the following detailed description in conjunction with the figures. The detailed description and figures provide merely examples of the various embodiments of the cooling systems. Many variations are contemplated for different applications and design considerations; however, for the sake of brevity and clarity, all the contemplated variations may not be individually described in the following detailed description. Those skilled in the art will understand how the disclosed examples may be varied, modified, and altered and not depart in substance from the scope of the examples described herein.

A conventional cooling system may include fluids to transfer heat from an object to the surrounding environment. One type of conventional cooling system is a two-phase, immersion cooling system. Two-phase immersion required large quantities of expensive fluid to immerse object, e.g., electronics, being cooled. In the conventional cooling systems, the containment area needs to be airtight for proper functioning. This, however, prevents ingress/egress into the containment area without fluid loss (via gasification). Another type of cooling system is a single-phase immersion cooling system. Single-phase immersion lacks the efficiency of two-phase immersion. Moreover, the single-phase fluid carries less energy per watt used to cool the containment area and requires a substantially higher flow rate per British Thermal Unit (BTU) removed.

Implementation of cooling systems according to the present invention may address some or all of the problems described above. In embodiments, a cooling system utilizes dielectric, single-phase fluid and dielectric two-phase fluid in a single containment area. A container (heat source) with a piece of electronics can be submerged in the single-phase fluid and the two-phase fluid. The container is positioned to give high performance components, which typically have high heat generation, access to superior cooling via the two-phase fluid and the remaining components can be cooled via the single-phase fluid. Due to a greater density of two-phase fluid, the two-phase fluid and the single-phase fluid remain separated and/or substantially separated and, the single-phase fluid sits on top of two-phase fluid, when oriented relative to gravity. In embodiments, the single-phase fluid has a greater density thus reversing the orientation of the fluids.

In embodiments, the single-phase fluid and the two-phase fluid can be liquids. The components expel their heat into the two-phase fluid which boils and carries the two-phase fluid in gas form through the two-phase fluid and through the lighter single-phase fluid, where the gas (former two-phase liquid) is released into a pocket of air (or inert gas) located above the fluid layers within the containment area. Once the gas reaches the air pocket, the gas (from the two-phase fluid) will condense again via the heat exchanger located in thermal communication with the air pocket of the containment area. In one example, a heat exchanger may be a device that facilitates the process of heat exchange between two or more fluids. In one embodiment, the fluids may be at different temperatures. In another embodiment, the fluids may be at the same temperature. In another embodiment, the fluids may be different types of fluids. In another example, the heat exchanger may be a condenser coil that can be located in the air pocket of the containment area. Once heat is transferred to the heat exchanger, the gas of the two-phase liquid will condense and pass back through the single-phase fluid layer to the two-phase fluid layer. This cycle repeats thereby cooling the heat source within the containment area. In some embodiments, the heat exchanger can be located in a separate compartment or container.

Additionally, heat expelled into the upper portion of the tank accumulates in the single-phase fluid and can be pumped separately or can be left as-is and will bring the two-phase fluid at the boundary to a boil, releasing the heat and recycling the fluid. The single-phase fluid adds the additional benefit of allowing ingress/egress to the tank (cables for instance) without losing the two-phase fluid since the ingress/egress would be in the single-phase fluid portion, e.g., submerged in the single-phase fluid. Further, the single-phase fluid doubles as a natural seal since the gas in the top of the containment area cannot exit (much the same way as air can be trapped in a canoe that is upside down).

For example, a containment area for two or more fluids (which can be dielectric fluids), a condenser coil (for fluid such as water (a non-dielectric liquid) or water glycol mixture, but not limited to) and electronics to cool. Optionally, the containment area can include a secondary pump to cool the single-phase fluid independently of the condenser coil. Additionally, the condenser coil could include a plate inside or outside of the containment area (if outside, the cooler temp surrounding the containment area (which could be caused by another fluid, a cold plate, and/or cold air) would cause the gas to condense.

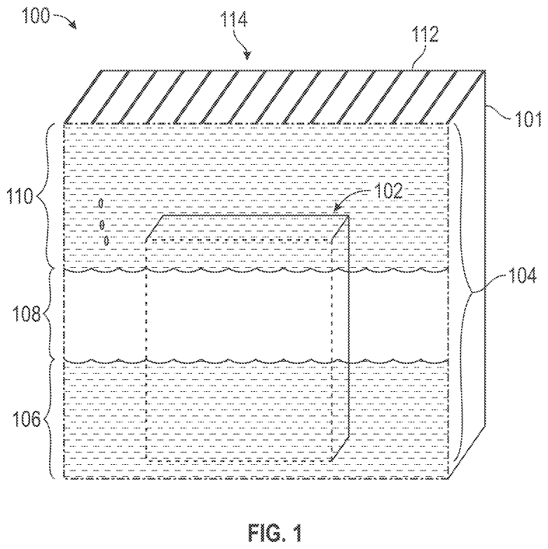

FIG. 1 illustrates a cooling system 100 for cooling a heat source 102, according to an embodiment. The cooling system 100 utilizes multiple layers of cooling fluids to cool the heat source 102. The heat source 102 is positioned to give high performance components, which typically have high heat generation, access to one type of fluid and the remaining components can be cooled via another type of fluid.

As illustrated in FIG. 1, the cooling system 100 includes a cooling housing 101 that forms a containment area 104. The heat source 102 is placed within the containment area 104. The heat source 102 can be any type of object, device, item, etc. that is desirable to cool. In an embodiment, the heat source 102 can be one or more electronic devices that need to be cooled. While FIG. 1 illustrates the cooling housing 101 being formed as a square or rectangular cube, one skilled in the art will realize that the cooling housing 101 represented in FIG. 1 is a generalized example and that the cooling housing 101 can be formed in any shape and any dimensions. Likewise, while FIG. 1 illustrates the containment area 104 being formed as a hollow cavity, one skilled in the art will realize that the containment area 104 represented in FIG. 1 is a generalized example and that the containment area 104 can be formed in any shape and any dimensions.

The containment area 104 of the cooling housing 101 includes a first fluid layer 106. The first fluid layer 106 is positioned within the containment area 104 (or the heat source 102 is positioned within the containment area 104) such that the first fluid layer 106 surrounds a first portion of the heat source 102). In some embodiments, the heat source 102 can be positioned such that the first fluid layer 106 surround a first portion of the heat source 102 that produces the most heat. For example, the first fluid layer 106 can be adjacent to electronic components that produce heat. In some embodiment, the first fluid layer 106 can include a two-phase liquid, for example, two-phase Novec by 3M, Fluorinert by 3M, and the like.

The containment area 104 also includes a second fluid layer 108. The second fluid layer 108 is positioned within the containment area 104 (or the heat source 102 is positioned within the containment area 104) such that the second fluid layer 108 surrounds a second portion of the heat source 102). The second fluid layer 108 is positioned within the containment area 104 such that the first fluid layer 106 and the second fluid layer 108 are substantially separated. In embodiments, the second fluid layer 108 can include a single-phase liquid. In embodiments, the first fluid layer 106 can have a density that is higher relative to the second fluid layer 108. As such, when the housing is oriented relative to gravity, the first fluid layer 106 settles at a lower portion of the containment area 104 and the second fluid layer 108 is positioned on top of the first fluid layer 106. In some embodiments, the first fluid layer 106 can include a single-phase liquid and the second fluid layer 108 can include a two-phase liquid. As described herein, separated and/or substantially separated means that the one of ordinary skill in the art, however, will realize that the fluid layers may intermix at the interface been the fluid layers as governed by the physical properties of the fluids being used. In one embodiment, the containment area 104 may include different single phase fluids in the same container, such as single phase fluids with different energy or watt characteristics.

The containment area 104 also includes an nth fluid layer 110. The nth fluid layer 110 is positioned within the containment area 104 (or the heat source 102 is positioned within the containment area 104) such that the nth fluid layer 110 surrounds a third portion of the heat source 102). The nth fluid layer 110 is positioned within the containment area 104 such that the nth fluid layer 110 and the second fluid layer 108 are substantially separated. In embodiments, the nth fluid layer 110 can include a gas such as air. In embodiment, the nth fluid layer 110 can have a density lower than the second fluid layer 108. As such, the nth fluid layer 110 can be located at a top portion of the containment area 104, relative to gravity, above the second fluid layer 108.

While not illustrated, the containment area 104 can include more than one of the second fluid layer 108. That is, the multiple second fluid layers 108 (third, fourth, fifth, sixth, seventh, etc.) can be interposed between the nth fluid layer 110 and the first fluid layer 106. In some embodiments, the multiple second fluid layers 108 can include the same type of fluid. In some embodiments, the multiple second fluid layers 108 can include different types of fluids. In embodiments, the multiple second fluid layers 108 can each have a different density, thereby forming a continuum of second fluid layers 108.

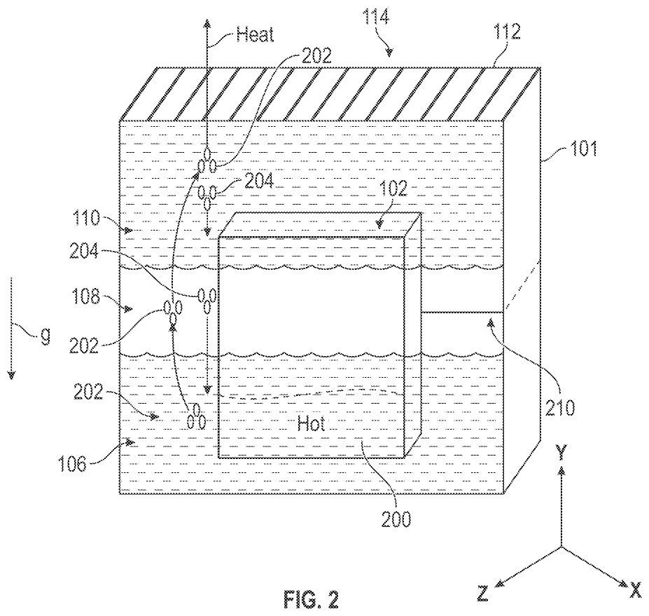

The cooling housing 101 also includes a heat exchanger 112. The heat exchanger 112 is positioned to be in thermal communication with the nth fluid layer 110 and an environment 114 surrounding the housing 101. The heat exchanger 112 transfers heat from the containment area 104, via the first fluid layer 106, the second fluid layer 108, and the nth fluid layer 110 to the environment 114 surrounding the housing 101, as described below in FIG. 2. In embodiments, the heat exchanger 112 can include a heat pump, a refrigerator system, a heat sink, a fan, or the like. In another embodiment, the heat exchanger 112 may be located outside the housing such as in a different location. In another embodiment, the heat exchanger 112 may be located in a different compartment of the cooling housing 101.

In some embodiments, the heat exchanger 112 can be located in one or more separate compartments or containers. The separate compartment or container containing the heat exchanger can be removable or detachable from the housing 101. In this example, gas from the nth fluid layer can be separated or sequestered in the one or more separate compartments or containers to interact with the heat exchanger.

FIG. 2 illustrates an operation cooling system 100 for cooling a heat source 102, according to an embodiment. The cooling system 100 utilizes multiple layers of cooling fluids to cool the heat source 102. The hottest portions of the heat source 102 are positioned with the first fluid layer 106, thereby utilizing the superior thermal properties of the first fluid layer 106.

As illustrated, the heat source 102, for example, a container with electronics 200, can be submerged into the first fluid layer 106 and the second fluid layer 108. The heat source 102 is positioned to give the electronics 200, which typically have high heat generation, access to superior cooling via the first fluid layer 106, and the remaining components can be cooled via the second fluid layer 108. Due to a greater density of the first fluid layer 106, the first fluid layer 106 and the second fluid layer 108 fluid remain substantially separated and, the second fluid layer 108 sits on top of two-phase fluid, when oriented relative to gravity, g.

In embodiments, the electronics 200 expel their heat into the first fluid layer 106 which boils forming gas particles 202. The gas particles 202 travel through the second fluid layer 108, where gas particles 202 are released into the nth fluid layer 110, e.g., gas layer, location above the second fluid layer 108 within the containment area 104. Once the gas reaches the nth fluid layer 110 (or gas layer), the gas particles 202 contact component of the heat exchanger 112, thereby transferring heat into the environment 114. The loss of heat causes the gas particles 202 to condense into liquid particles 204. The liquid particles 204 fall back to the surface of the second fluid layer 108 and pass back through the second fluid layer 108 to the first fluid layer. This cycle repeats thereby cooling the heat source 102 within the containment area 104.

Additionally, heat expelled into the upper portion of the containment area 104 accumulates in the single-phase fluid and can be pumped separately or can be left as-is and will bring the first fluid layer 106 at the boundary to a boil, releasing the heat and recycling the fluid. The second fluid layer 108 adds the additional benefit of allowing ingress/egress to the tank (cables 210 for instance) without losing the two-phase fluid since the ingress/egress would be in the second fluid layer 108, e.g., submerged in the second fluid layer 108. Further, the second fluid layer 108 doubles as a natural seal since the gas in the top of the containment area 104 cannot exit (much the same way as air can be trapped in a canoe that is upside down).

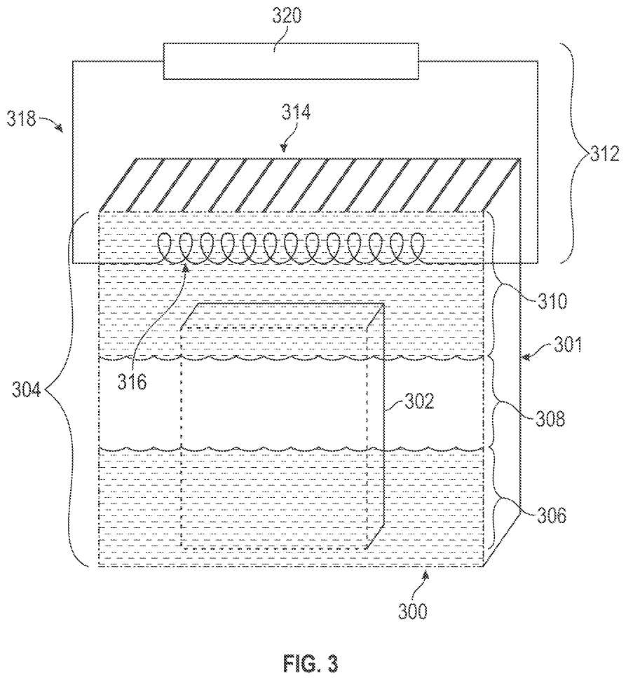

FIG. 3 illustrates a cooling system 300 for cooling a heat source 302, according to an embodiment. The cooling system 300 utilizes multiple layers of cooling fluids to cool the heat source 302. The cooling system 300 includes a heat pump 312 as a heat exchanger.

As illustrated in FIG. 3, the cooling system 300 includes a cooling housing 301 that forms a containment area 304. The heat source 302 is placed within the containment area 304. The heat source 302 can be any type of object, device, item, etc. that is desirable to cool. In an embodiment, the heat source 302 can be one or more electronic devices that need to be cooled. While FIG. 3 illustrates the cooling housing 301 being formed as a square or rectangular cube, one skilled in the art will realize that the cooling housing 301 represented in FIG. 3 is a generalized example and that the cooling housing 301 can be formed in any shape and any dimensions. Likewise, while FIG. 3 illustrates the containment area 304 being formed as a hollow cavity, one skilled in the art will realize that the containment area 304 represented in FIG. 3 is a generalized example and that the containment area 304 can be formed in any shape and any dimensions.

The containment area 304 of the cooling housing 301 includes a two-phase liquid layer 306. The two-phase liquid layer 306 is positioned within the containment area 304 (or the heat source 302 is positioned within the containment area 304) such that the two-phase liquid layer 306 surrounds a first portion of the heat source 302). In some embodiments, the heat source 302 can be positioned such that the two-phase liquid layer 306 surround a first portion of the heat source 302 that produces the most heat. In some embodiment, the two-phase liquid layer 306 can be Novec by 3M. The containment area 304 also includes a single-phase liquid layer 308. The single-phase liquid layer 308 is positioned within the containment area 304 (or the heat source 302 is positioned within the containment area 304) such that the single-phase liquid layer 308 surrounds a second portion of the heat source 302). The single-phase liquid layer 308 is positioned within the containment area 304 such that the two-phase liquid layer 306 and the single-phase liquid layer 308 are substantially separated.

In embodiments, the two-phase liquid layer 306 can have a density that is higher relative to the single-phase liquid layer 308. As such, when the housing is oriented relative to gravity, the two-phase liquid layer 306 settles at a lower portion of the containment area 304 and the single-phase liquid layer 308 is positioned on top of the two-phase liquid layer 306. As described herein, substantially separated means that the one of ordinary skill in the art, however, will realize that the fluid layers may intermix at the interface been the fluid layers as governed by the physical properties of the fluids being used.

The containment area 304 also includes a gas layer 310 (or third fluid). The gas layer 310 is positioned within the containment area 304 (or the heat source 302 is positioned within the containment area 304) such that the gas layer 310 surrounds a third portion of the heat source 302). The gas layer 310 is positioned within the containment area 304 such that the gas layer 310 and the single-phase liquid layer 308 are substantially separated. In embodiments, the gas layer 310 can include a gas such as air. In embodiment, the gas layer 310 can have a density lower than the single-phase liquid layer 308. As such, the gas layer 310 can be located at a top portion of the containment area 304, relative to gravity, above the single-phase liquid layer 308.

While not illustrated, the containment area 304 can include more than one of the single-phase liquid layers 308 (this can be referred to as the third, fourth, or fifth liquid layer, and the gas layer can subsequently be numbered higher or referred to as gas layer). That is, the multiple single-phase liquid layer 308 can be interposed between the gas layer 310 and the two-phase liquid layer 306. In some embodiments, the multiple single-phase liquid layer 308 can include the same type of fluid. In some embodiments, the multiple second single-phase liquid layer 308 can include different types of fluids. In embodiments, the multiple single-phase liquid layer 308 can each have a different density, thereby forming a continuum of single-phase liquid layer 308.

The cooling housing 301 can also includes a heat pump 312 as a heat exchanger. The heat pump 312 can include a condenser coil 316 coupled to cooling devices 320 by a supply line 318. The cooling device can include a fan, a radiator, a heat sink, etc. The condenser coil 316 is positioned to be in thermal communication with the gas layer 310. The condenser coil 316 transfers heat from the containment area 304, via the two-phase liquid layer 306, the single-phase liquid layer 308, and the gas layer 110 to the environment 314 surrounding the housing 301, as described above in FIG. 2. That is, heat is transferred to the fluid in the condenser coil 316 to the cooling devices 320 to be transferred to the environment 314.

For example, the condenser fluid, e.g., water/glycol/other mixture, circulates through the radiator. The single-phase liquid layer 308 on top of the two-phase liquid layer 306 offers direct cooling to the components that are generally producing less thermal energy and as that fluid raises to the temperature of the two-phase threshold, it will cause the two-phase liquid layer 306 to boil (where they meet) allowing for the heat transfer from the lower density components. The boil can be at a constant boiling, slow boiling, low boiling, and intermediate levels thereof. The two-phase liquid layer 306 once condensed, will either rain down or be directed in some manner (directed rain or collecting and funneling back to be processed again).

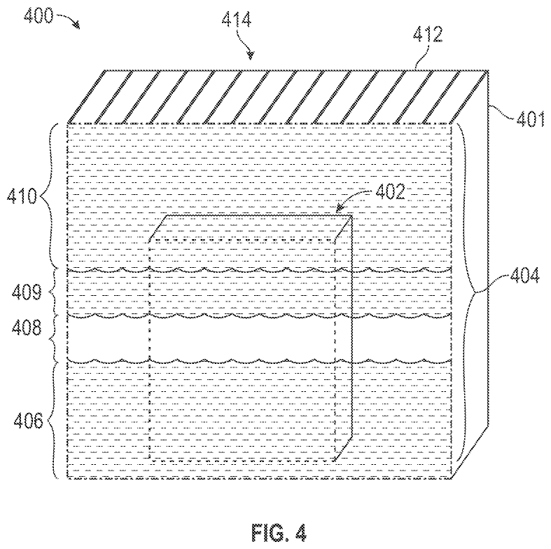

FIG. 4 illustrates a cooling system 400 for cooling a heat source 402, according to an embodiment. The cooling system 400 utilizes multiple layers of cooling fluids to cool the heat source 402.

As illustrated in FIG. 4, the cooling system 400 includes a cooling housing 401 that forms a containment area 404. The heat source 402 is placed within the containment area 404, as described above in FIGS. 1-3. The containment area 404 of the cooling housing 401 includes a two-phase liquid layer 406. The containment area 404 also includes a single-phase liquid layer 408. The two-phase liquid layer 406 and the single-phase liquid layer 408 can be similar to those described above.

The containment area 404 also includes a non-dielectric fluid layer 409. In embodiments, the non-dielectric fluid layer 409 can have a density that is lower relative to the single-phase liquid layer 408. As such, when the housing is oriented relative to gravity, the non-dielectric fluid layer 409 is positioned on top of the single-phase liquid layer 408. For example, water can be positioned on the top of the single-phase liquid layer above the dielectric fluids. In this example, the water may be visible to provide a decorative and pleasant appearance.

The containment area 404 also includes a gas layer 410. The gas layer 410 is positioned within the containment area 404 (or the heat source 402 is positioned within the containment area 404) such that the gas layer 410 surrounds a portion of the heat source 402). The gas layer 410 is positioned within the containment area 404 such that the gas layer 410 and the s non-dielectric fluid layer 409 are substantially separated. In embodiments, the gas layer 410 can include a gas such as air. In embodiment, the gas layer 410 can have a density lower than the non-dielectric fluid layer 409. As such, the gas layer 410 can be located at a top portion of the containment area 404, relative to gravity, above the single-phase liquid layer 408. While not illustrated, the containment area 404 can include more than one single-phase liquid layer 408, as described. The housing 401 can also include a heat exchanger 412, as described above.

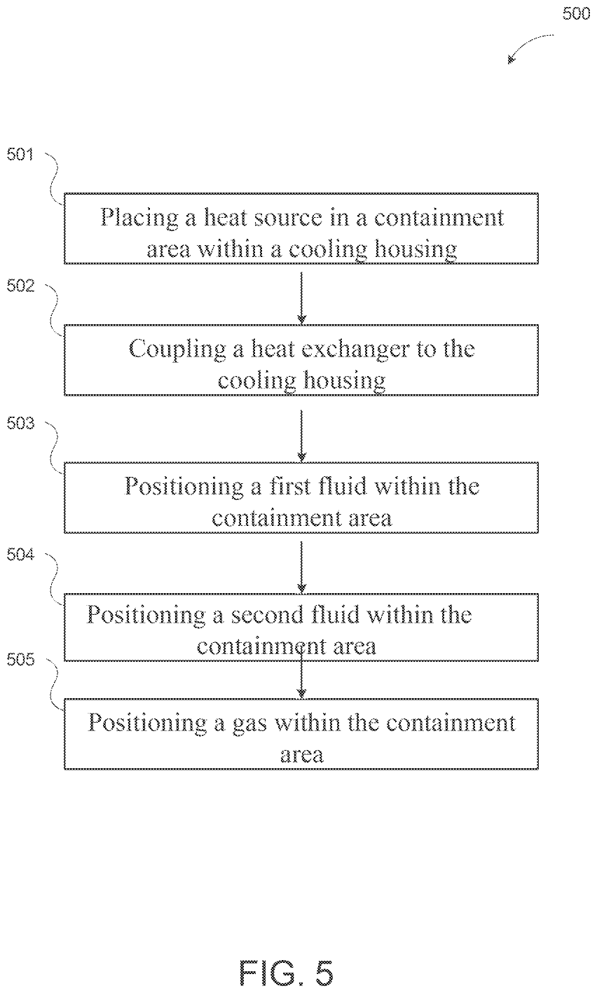

FIG. 5 illustrates a block chart of a method 500 of using a cooling system to removing heat from a heat source, according to an embodiment. In an embodiment, step 501 includes placing a heat source in a containment area within a cooling housing. The containment area is configured to receive the heat source. Step 502 includes coupling a heat exchanger to the housing. In one embodiment, the housing may be coupled to the heat exchange by attaching the heat exchange directly to the housing. In another embodiment, the housing may be coupled to the heat exchange indirectly via a connection such as tubes, pipes, plumbing, and so forth. The heat exchanger is configured to transfer heat from the containment area to an environment surrounding the cooling housing. Step 503 includes positioning a first fluid within the containment area. The first fluid surrounds a first portion of the heat source, and the first fluid includes a two-phase liquid. Step 504 includes positioning a second fluid within the containment area. The second fluid surrounds a second portion of the heat source; and the second fluid includes a single-phase liquid. Step 505 includes positioning a gas within the containment area. The gas is in thermal contact with the second fluid and a portion of the heat exchanger. The first fluid is configured to receive heat, boil and form gas particles, travel upwards through the second fluid and the gas, contact the heat exchanger, lose heat to the heat exchanger, condense into a liquid, travel down through the gas and the second fluid, and return to the first portion of the heat source within the containment area.

Embodiments include methods wherein the second fluid allows ingress and egress to the containment area whereby a user can access the heat source without losing gas or the first fluid.

Embodiments include methods wherein the second fluid can be maintained at a temperature to provide a constant boiling of the first fluid at a boundary between the first fluid and the second fluid.

Embodiments include methods wherein the second fluid is cooled by a second heat exchanger to reduce a temperature of the second fluid and slow boiling of the first fluid.

A feature illustrated in one of the figures may be the same as or similar to a feature illustrated in another of the figures. Similarly, a feature described in connection with one of the figures may be the same as or similar to a feature described in connection with another of the figures. The same or similar features may be noted by the same or similar reference characters unless expressly described otherwise. Additionally, the description of a particular figure may refer to a feature not shown in the particular figure. The feature may be illustrated in and/or further described in connection with another figure.

The foregoing description sets forth numerous specific details such as examples of specific systems, components, methods and so forth, in order to provide a good understanding of several implementations. It will be apparent to one skilled in the art, however, that at least some implementations may be practiced without these specific details. In other instances, well-known components or methods are not described in detail or are presented in simple block diagram format in order to avoid unnecessarily obscuring the present implementations. Thus, the specific details set forth above are merely exemplary. Particular implementations may vary from these exemplary details and still be contemplated to be within the scope of the present implementations.

Related elements in the examples and/or embodiments described herein may be identical, similar, or dissimilar in different examples. For the sake of brevity and clarity, related elements may not be redundantly explained. Instead, the use of a same, similar, and/or related element names and/or reference characters may cue the reader that an element with a given name and/or associated reference character may be similar to another related element with the same, similar, and/or related element name and/or reference character in an example explained elsewhere herein. Elements specific to a given example may be described regarding that particular example. A person having ordinary skill in the art will understand that a given element need not be the same and/or similar to the specific portrayal of a related element in any given figure or example in order to share features of the related element.

It is to be understood that the foregoing description is intended to be illustrative and not restrictive. Many other implementations will be apparent to those of skill in the art upon reading and understanding the above description. The scope of the present implementations should, therefore, be determined with reference to the appended claims, along with the full scope of equivalents to which such claims are entitled.

The foregoing disclosure encompasses multiple distinct examples with independent utility. While these examples have been disclosed in a particular form, the specific examples disclosed and illustrated above are not to be considered in a limiting sense as numerous variations are possible. The subject matter disclosed herein includes novel and non-obvious combinations and sub-combinations of the various elements, features, functions and/or properties disclosed above both explicitly and inherently. Where the disclosure or subsequently filed claims recite “a” element, “a first” element, or any such equivalent term, the disclosure or claims is to be understood to incorporate one or more such elements, neither requiring nor excluding two or more of such elements.

As used herein “same” means sharing all features and “similar” means sharing a substantial number of features or sharing materially important features even if a substantial number of features are not shared. As used herein “may” should be interpreted in a permissive sense and should not be interpreted in an indefinite sense. Additionally, use of “is” regarding examples, elements, and/or features should be interpreted to be definite only regarding a specific example and should not be interpreted as definite regarding every example. Furthermore, references to “the disclosure” and/or “this disclosure” refer to the entirety of the writings of this document and the entirety of the accompanying illustrations, which extends to all the writings of each subsection of this document, including the Title, Background, Brief description of the Drawings, Detailed Description, Claims, Abstract, and any other document and/or resource incorporated herein by reference.

As used herein regarding a list, “and” forms a group inclusive of all the listed elements. For example, an example described as including A, B, C, and D is an example that includes A, includes B, includes C, and also includes D. As used herein regarding a list, “or” forms a list of elements, any of which may be included. For example, an example described as including A, B, C, or D is an example that includes any of the elements A, B, C, and D. Unless otherwise stated, an example including a list of alternatively-inclusive elements does not preclude other examples that include various combinations of some or all of the alternatively-inclusive elements. An example described using a list of alternatively-inclusive elements includes at least one element of the listed elements. However, an example described using a list of alternatively-inclusive elements does not preclude another example that includes all of the listed elements. And, an example described using a list of alternatively-inclusive elements does not preclude another example that includes a combination of some of the listed elements. As used herein regarding a list, “and/or” forms a list of elements inclusive alone or in any combination. For example, an example described as including A, B, C, and/or D is an example that may include: A alone; A and B; A, B and C; A, B, C, and D; and so forth. The bounds of an “and/or” list are defined by the complete set of combinations and permutations for the list.

Where multiples of a particular element are shown in a FIG., and where it is clear that the element is duplicated throughout the FIG., only one label may be provided for the element, despite multiple instances of the element being present in the FIG. Accordingly, other instances in the FIG. of the element having identical or similar structure and/or function may not have been redundantly labeled. A person having ordinary skill in the art will recognize based on the disclosure herein redundant and/or duplicated elements of the same FIG. Despite this, redundant labeling may be included where helpful in clarifying the structure of the depicted examples.

The Applicant(s) reserves the right to submit claims directed to combinations and sub-combinations of the disclosed examples that are believed to be novel and non-obvious. Examples embodied in other combinations and sub-combinations of features, functions, elements and/or properties may be claimed through amendment of those claims or presentation of new claims in the present application or in a related application. Such amended or new claims, whether they are directed to the same example or a different example and whether they are different, broader, narrower or equal in scope to the original claims, are to be considered within the subject matter of the examples described herein.

1. A device, comprising:
a cooling housing comprising:
a containment area,
wherein the containment area is configured to receive a heat source;
a heat exchanger coupled to the cooling housing,
wherein the heat exchanger is configured to transfer heat from the containment area to an environment surrounding the cooling housing;
a first fluid,
wherein the first fluid is:
positioned within the containment area,
surrounds a first portion of the heat source, and
a two-phase liquid;
a second fluid,
wherein the second fluid:
is positioned within the containment area,
surrounds a second portion of the heat source, and
is a single-phase liquid;
wherein the first fluid is separate from the second fluid;
a third fluid,
wherein the third fluid is:
positioned within the containment area,
surrounds a third portion of the heat source, and
is a liquid;
wherein the first fluid, second fluid and third fluid are separated; and
a gas,
wherein the gas is:
positioned in thermal contact with a portion of the third fluid, and
positioned in a fourth portion of the heat source.

2. The device of claim 1, wherein:
the first fluid has a greater density than the second fluid,
the second fluid has a greater density than the third fluid, and
the third fluid has a greater density than the gas.

3. The device of claim 1, wherein:
the first fluid is a dielectric fluid,
the second fluid is dielectric fluid,
the third fluid is a non-dielectric fluid, and
the gas is an inert gas.

4. The device of claim 1, wherein:
the first fluid surrounds a hottest portion of the heat source, and
the second fluid surrounds a second hottest portion of the heat source.

5. The device of claim 1, wherein:
the second portion of the heat source surrounded by the second fluid is configured to be cooled by a second heat exchanger.

6. The device of claim 1, wherein the heat exchanger further comprises:
a condenser, and
plate configured to condense gas.

7. The device of claim 6, wherein the heat exchanger:
is configured to be removable from the cooling housing, and
the third fluid is configured to be removed with the heat exchanger.

8. The device of claim 1, wherein the heat exchanger:
is a heat pump, and
is positioned within the containment area.

9. A method, comprising:
placing a heat source in a containment area within a cooling housing,
wherein the containment area is configured to receive the heat source;
coupling a heat exchanger to the cooling housing,
wherein the heat exchanger is configured to transfer heat from the containment area to an environment surrounding the cooling housing;
positioning a first fluid within the containment area,
wherein:
the first fluid surrounds a first portion of the heat source, and
the first fluid includes a two-phase liquid, and
positioning a second fluid within the containment area,
wherein:
the second fluid surrounds a second portion of the heat source; and
the second fluid includes a single-phase liquid,
positioning a gas within the containment area,
wherein:
the gas is in thermal contact with the second fluid and a portion of the heat exchanger;
wherein the first fluid is configured to:
receive heat,
boil and form gas particles,
travel upwards through the second fluid and the gas,
contact the heat exchanger,
lose heat to the heat exchanger,
condense into a liquid,
travel down through the gas and the second fluid, and
return to the first portion of the heat source within the containment area.

10. The method of claim 9, further comprising:
a third fluid positioned between the second fluid and the gas,
wherein the third fluid is a non-dielectric liquid.

11. The method of claim 9, wherein:
the heat exchanger is positioned outside the cooling housing, and
heat is transferred to the heat exchanger via a condenser coil coupled to a cooling device.

12. The method of claim 9, wherein:
the second fluid allows ingress and egress to the containment area whereby a user can access the heat source without losing gas or the first fluid.

13. The method of claim 9, wherein:
the second fluid can be maintained at a temperature to provide a constant boiling of the first fluid at a boundary between the first fluid and the second fluid.

14. The method of claim 9, wherein:
the second fluid is cooled by a second heat exchanger to reduce a temperature of the second fluid and slow boiling of the first fluid.

15. The method of claim 14, further comprising:
a third fluid positioned between the second fluid and the gas,
wherein:
the third fluid is a single-phase fluid, and
the third fluid has a density lower than the second fluid and greater than the gas.

16. A system, comprising:
a cooling housing comprising:
a containment area,
wherein the containment area is configured to receive a heat source;
a heat exchanger coupled to the cooling housing,
wherein the heat exchanger is configured to transfer heat from the containment area to an environment surrounding the cooling housing;
a first fluid,
wherein the first fluid is positioned:
within the containment area, and
surrounding a first portion of the heat source;
a second fluid,
wherein the second fluid is positioned:
within the containment area, and
surrounding a second portion of the heat source;
wherein the first fluid and second fluid are separate; and
a gas,
wherein the gas is positioned:
in thermal contact with a portion of the second fluid, and
a portion of the heat exchanger.

17. The system of claim 16, wherein:
the first fluid is a two-phase liquid,
the second fluid is a single-phase liquid, and
the gas is air.

18. The system of claim 16, further comprising:
a second heat exchanger positioned in the second fluid,
wherein the second heat exchanger comprises:
a supply line,
a condenser coil, and
a heat pump.

19. The system of claim 16, wherein:
the heat exchanger is positioned outside the cooling housing, and
heat exchanger is positioned in a removable compartment.

20. The system of claim 16, wherein:
the first fluid has a greater density than the second fluid, and
the first portion of the heat source produces more heat than the second portion of the heat source.
